(19) United States
(12) Patent Application Publication
(10) Pub. No.: US 2025/0293457 A1
(43) Pub. Date: Sep. 18, 2025

(54) INFORMATION PROCESSING APPARATUS AND CONNECTOR

(71) Applicant: Kioxia Corporation, Tokyo (JP)

(72) Inventors: Naoki HAYASHI, Hiratsuka Kanagawa (JP); Kenta IWASAKI, Yokohama Kanagawa (JP); Koichi SATO, Yokohama Kanagawa (JP); Takeaki SERIZAWA, Hiratsuka Kanagawa (JP)

(21) Appl. No.: 19/078,114

(22) Filed: Mar. 12, 2025

(30) Foreign Application Priority Data
Mar. 18, 2024 (JP) 2024-042718

(51) Int. Cl. H01R 13/533; G06F 1/20

(52) U.S. Cl. CPC H01R 13/533; G06F 1/20

(57) ABSTRACT

An information processing apparatus employs a connector structure that enables a male connector and a female connector to be easily fitted together while being immersed in coolant. The information processing apparatus includes a male connector and a female connector. The male connector includes an insertion portion. The female connector includes an outer surface, a concavity, and a coolant channel. The concavity extends from the outer surface in a first direction and is configured to house the insertion portion. The channel extends from a portion of the concavity to outside the female connector and through which coolant passes when the insertion portion is inserted into the concavity while the male connector and the female connector are placed in the coolant, wherein the portion is located between an end of the insertion portion in the first direction and an end of the concavity in the first direction.

### CROSS-REFERENCE TO RELATED APPLICATION(S)

This application is based upon and claims the benefit of priority from Japanese Patent Application No. 2024-042718, filed Mar. 18, 2024, the entire contents of which are incorporated herein by reference.

### FIELD

Embodiments described herein relate generally to an information processing apparatus and a connector.

### BACKGROUND

Various components mounted in an information processing apparatus generate heat while operating. A known system of cooling the components is immersion cooling. For example, a device including the components is immersed in an insulating coolant and cooled by the coolant.

There are cases where an operation of fitting a male connector and a female connector together is performed in coolant. When an insertion portion of the male connector is inserted into a concavity of the female connector, coolant collecting at a deep portion of the concavity may hinder the insertion portion from entering the concavity.

### BRIEF DESCRIPTION OF THE DRAWINGS

FIG. 1 is an exemplary sectional view schematically illustrating a test apparatus according to a first embodiment.

FIG. 2 is an exemplary perspective view of a test unit in the first embodiment illustrated with a partial cutaway.

FIG. 3 is an exemplary block diagram schematically illustrating the configuration of an SSD in the first embodiment.

FIG. 4 is an exemplary perspective view illustrating a male connector in the first embodiment.

FIG. 5 is an exemplary perspective view illustrating a female connector in the first embodiment.

FIG. 6 is an exemplary plan view illustrating the male connector and the female connector in the first embodiment.

FIG. 7 is an exemplary sectional view taken along line F7-F7 in FIG. 6, illustrating the male connector and the female connector in the first embodiment.

FIG. 8 is an exemplary sectional view taken along line F8-F8 in FIG. 6, illustrating the male connector and the female connector in the first embodiment.

FIG. 9 is an exemplary sectional view partially illustrating the male connector and the female connector in the first embodiment in an enlarged manner.

FIG. 10 is an exemplary sectional view illustrating the male connector that is being inserted into the female connector in the first embodiment.

FIG. 11 is an exemplary plan view illustrating a male connector and a female connector according to a second embodiment.

FIG. 12 is an exemplary perspective view illustrating a female connector according to a third embodiment.

FIG. 13 is an exemplary sectional view illustrating a female connector in the third embodiment.

### DETAILED DESCRIPTION

Embodiments provide an information processing apparatus and a connector that enable a male connector and a female connector to be fitted together in coolant.

In general, according to one embodiment, an information processing apparatus includes a male connector and a female connector. The male connector includes an insertion portion. The female connector includes an outer surface, a concavity, and a coolant channel. The concavity extends from the outer surface in a first direction and is configured to house the insertion portion. The channel extends from a portion of the concavity to outside the female connector and through which coolant passes when the insertion portion is inserted into the concavity while the male connector and the female connector are placed in the coolant, wherein the portion is located between an end of the insertion portion in the first direction and an end of the concavity in the first direction.

### First Embodiment

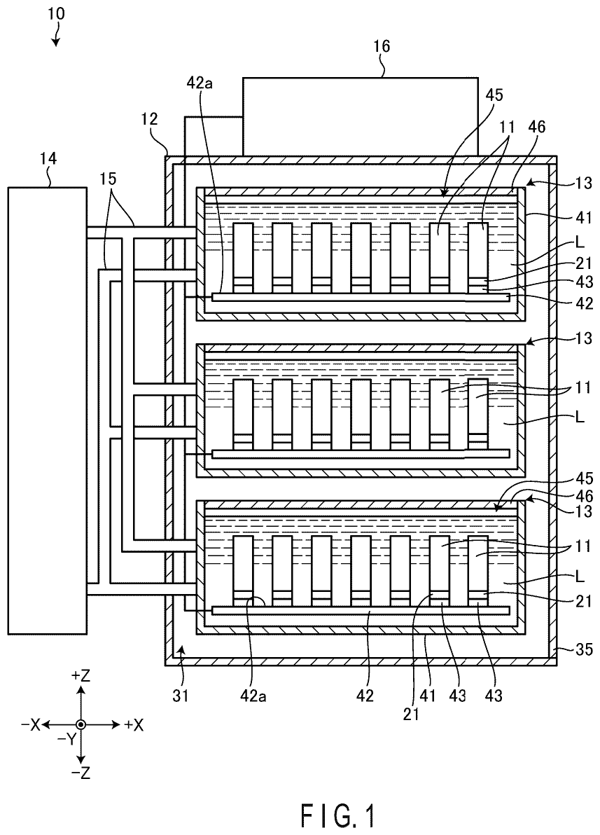

With reference to FIG. 1 to FIG. 6, a first embodiment will be described below. Note that, basically, a vertically upward direction is herein defined as an upward direction, and a vertically downward direction is herein defined as a downward direction. In the present description, the same constituent elements according to embodiments and the description thereof may be described using multiple expressions. The constituent elements and the description thereof are merely examples and are not limited to the expressions used in the present description. The constituent elements may be specified with names different from those used in the present description. Furthermore, the constituent elements may be described using expressions different from those used in the present description.

In the following description, the verb “restrain” is defined as, for example, preventing the occurrence of an event, an action, or an impact or reducing the degree of the event, the action or the impact. In the following description, the verb “constrain” is defined as, for example, preventing a movement or a rotation, or allowing a movement or a rotation within a predetermined range while preventing a movement or a rotation outside the predetermined range.

FIG. 1 is an exemplary sectional view schematically illustrating a test apparatus 10 according to the first embodiment. For example, the test apparatus 10 tests solid state drives (SSD) 11 in the process of manufacturing the SSDs 11. The test apparatus 10 is an example of an information processing apparatus.

As illustrated in each figure, a +X direction, a −X direction, a +Y direction, a −Y direction, a +Z direction, and a −Z direction are herein defined for the sake of convenience. The +X direction is a direction along the width of the test apparatus 10, and the −X direction is the opposite direction of the +X direction. The +Y direction is a direction along the depth of the test apparatus 10, and the −Y direction is the opposite direction of the +Y direction. The +Z direction is a direction along the height of the test apparatus 10, and the −Z direction is the opposite direction of the +Z direction. For example, the +Z direction is an upward direction, and the −Z direction is a downward direction.

The test apparatus 10 in the present embodiment includes a housing 12, a plurality of test units 13, a heat exchanger 14, piping 15, and a controller 16. Note that the test apparatus 10 is not limited to this example. During the test, a plurality of SSDs 11 are loaded into the test apparatus 10. As a result, the test apparatus 10 further includes the SSDs 11.

The SSDs 11 each include a male connector 21. The male connector 21 can also be referred to as, for example, a plug. The male connector 21 is, for example, a connector that conforms to the peripheral component interconnect express (PCIe) standard. Note that the male connector 21 is not limited to this example. The SSDs 11 each further include various components such as a substrate and a NAND flash memory.

The housing 12 is provided with a chamber 31 inside the housing 12. The housing 12 houses the plurality of test units 13 in the chamber 31. The housing 12 includes a door 35 that can open and close the chamber 31. The door 35 can close the chamber 31 airtightly. Note that the door 35 is not limited to this example.

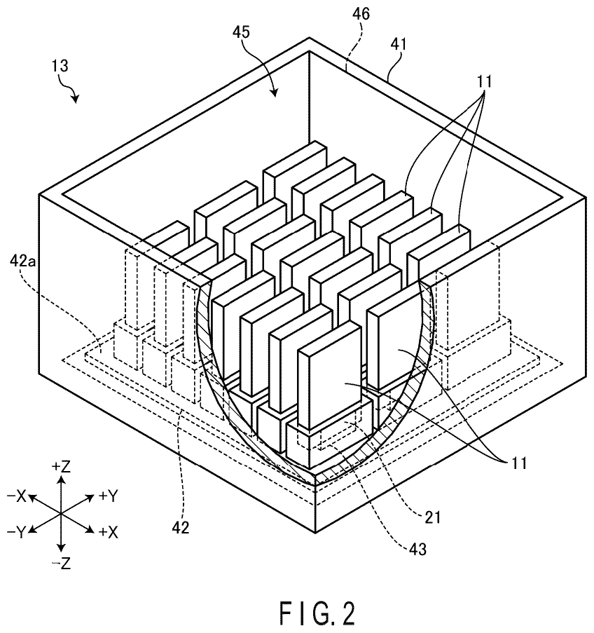

FIG. 2 is an exemplary perspective view of a test unit 13 in the first embodiment illustrated with a partial cutaway. As illustrated in FIG. 1 and FIG. 2, the plurality of test units 13 each include a case 41, a substrate 42, and a plurality of female connectors 43. The case 41 can also be referred to as a tank. The female connectors 43 are each an example of a female connector and a connector. The female connectors 43 can also be referred to as receptacles or sockets.

The case 41 is provided with a housing chamber 45 inside the case 41. The case 41 houses, in the housing chamber 45, the substrate 42, the plurality of female connectors 43, and the SSDs 11. The case 41 includes a lid 46 that can open and close the housing chamber 45. Note that, in FIG. 2, the lid 46 is omitted for understanding. The lid 46 can close the housing chamber 45 liquid-tightly. Note that the lid 46 is not limited to this example.

The housing chamber 45 is filled with coolant L. The coolant L can also be referred to as refrigerant. The coolant L is an insulating liquid. For example, the coolant L is a perfluorinated inert fluid (Fluorinert) or silicon oil. Note that the coolant L is not limited to this example.

The substrate 42 is, for example, a printed wiring board. The plurality of female connectors 43 are mounted on an upper surface 42a of the substrate 42 that substantially faces the +Z direction. The female connectors 43 are connectors that conform to the PCIe standard.

The substrate 42, the female connectors 43, and the SSDs 11 are immersed in the coolant L and cooled by the coolant L. In the coolant L, the male connectors 21 of the SSDs 11 are fitted into the plurality of female connectors 43. That is, the male connectors 21 and the female connectors 43 are placed in the coolant L. The SSDs 11 and the substrate 42 can transfer electric signals to each other through the male connectors 21 and the female connectors 43.

The heat exchanger 14 illustrated in FIG. 1 is connected to the plurality of test units 13 through the piping 15. The coolant L circulates between the heat exchanger 14 and the plurality of test units 13 through the piping 15. The heat exchanger 14 cools the coolant L warmed in the housing chamber 45. The heat exchanger 14 supplies the cooled coolant L to the housing chamber 45 again. Note that the heat exchanger 14 is not limited to this example. For example, the coolant L may be cooled in the housing chamber 45.

The controller 16 is electrically connected to the SSDs 11 via the substrates 42 and the female connectors 43 of the plurality of test units 13. For example, the controller 16 can obtain information from the SSDs 11 to diagnose the SSDs 11 and can record information such as firmware in the SSDs 11.

The controller 16 controls the heat exchanger 14. In addition, in the case where the test apparatus 10 performs an environment test, the controller 16 changes the temperature and the air pressure in the chamber 31 by controlling, for example, the heat exchanger and a pump.

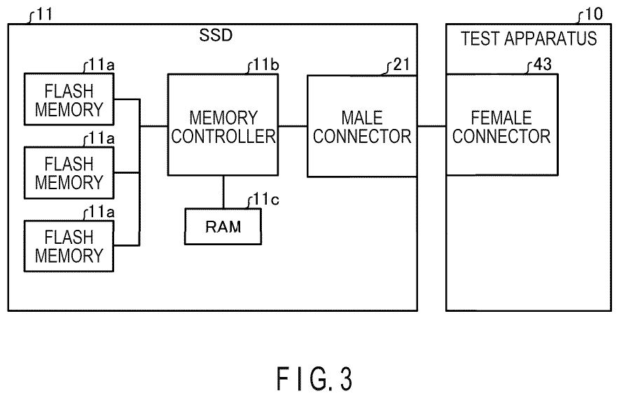

FIG. 3 is an exemplary block diagram schematically illustrating the configuration of an SSD 11 in the first embodiment. As illustrated in FIG. 3, the SSD 11 includes, for example, a plurality of flash memories 11a, a memory controller 11b, and a RAM 11c. Note that the SSD 11 may include a component other than the components mentioned above. The RAM 11c can also be referred to as a buffer memory.

The flash memories 11a are each, for example, a NAND flash memory. For example, the memory controller 11b includes various electronic circuits such as a processor and is electrically connected to the plurality of flash memories 11a, the RAM 11c, and the male connectors 21. The memory controller 11b controls the entire SSD 11 and communicates with a host such as the controller 16 via the male connector 21 and the female connector 43.

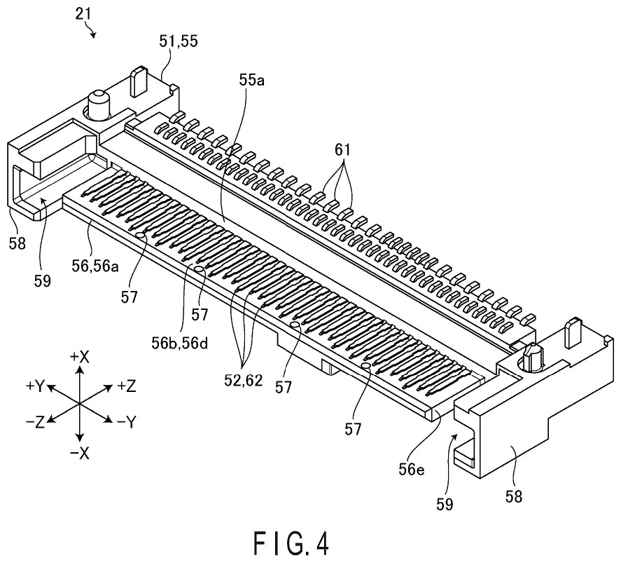

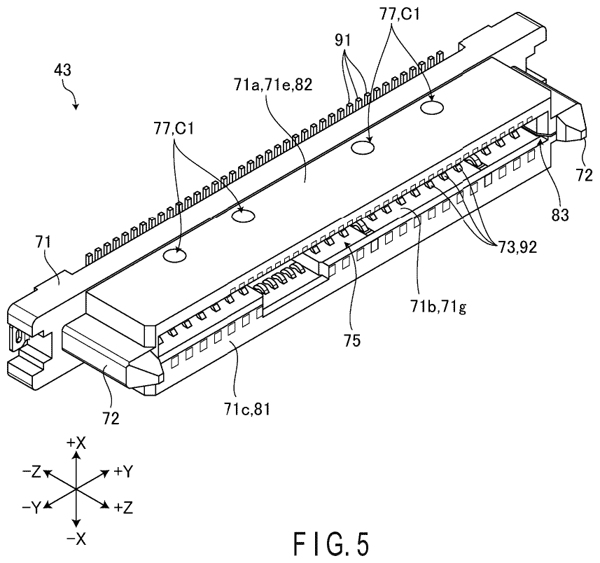

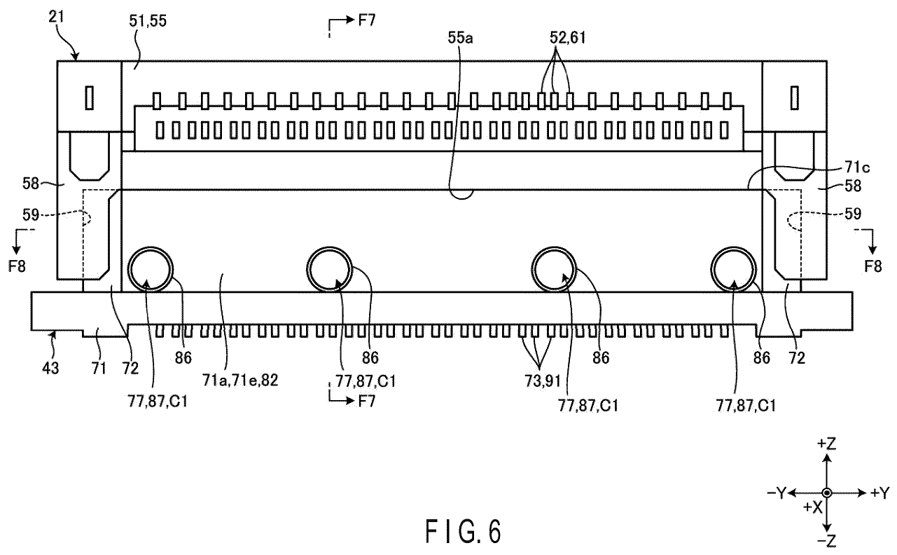

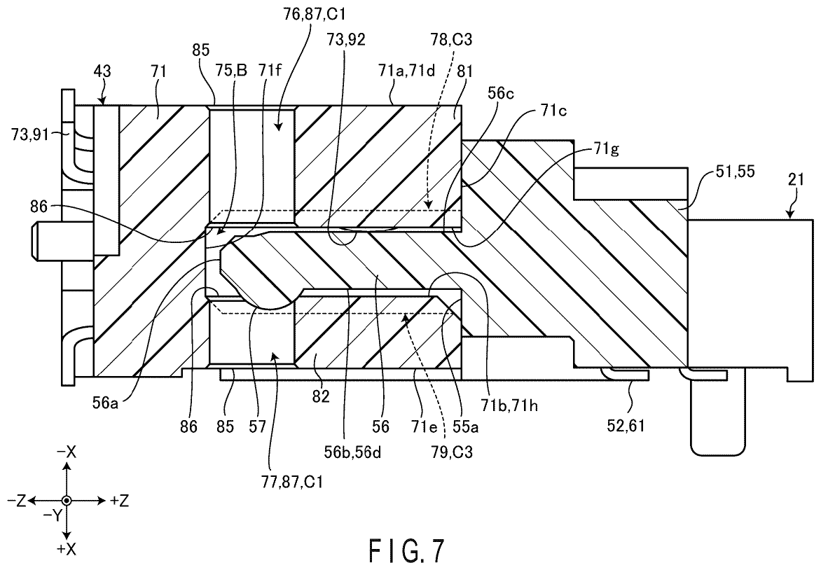

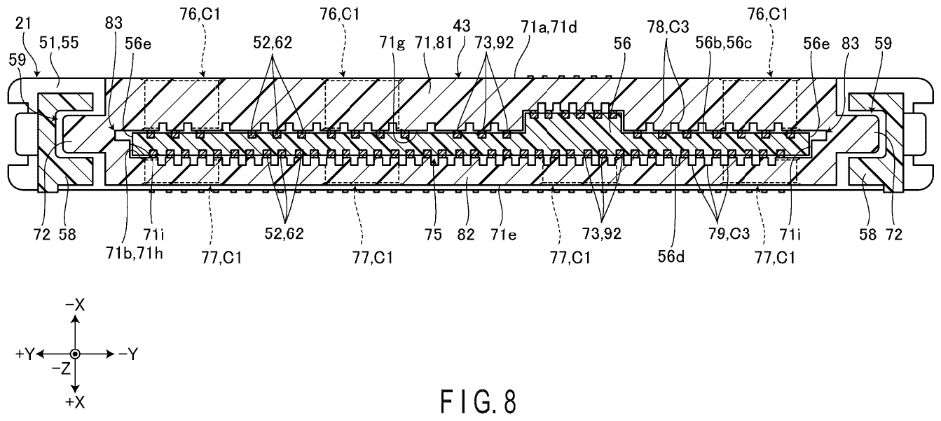

FIG. 4 is an exemplary perspective view illustrating the male connector 21 in the first embodiment. FIG. 5 is an exemplary perspective view illustrating the female connector 43 in the first embodiment. FIG. 6 is an exemplary plan view illustrating a state where the male connector 21 and the female connector 43 in the first embodiment are fitted together. FIG. 7 is an exemplary sectional view taken along the line F7-F7 in FIG. 6, illustrating the male connector 21 and the female connector 43 in the first embodiment. FIG. 8 is an exemplary sectional view taken along the line F8-F8 in FIG. 6, illustrating the male connector 21 and the female connector 43 in the first embodiment. In the figures, the female connector 43 is illustrated mainly with right-slanting hatching top right and the male connector 21 is illustrated mainly with left-slanting hatching.

As illustrated in FIG. 4, the male connector 21 includes a housing 51 and a plurality of contacts 52. Note that the male connector 21 is not limited to this example. The contacts 52 can also be referred to as pins.

The housing 51 is made of, for example, a synthetic resin and has insulation properties. As illustrated in FIG. 4 and FIG. 7, the housing 51 includes an attachment portion 55, an insertion portion 56, and protrusions 57. The protrusions 57 can also be referred to as lugs. As illustrated in FIG. 4, the housing 51 further includes two guides 58.

The attachment portion 55 is attached to a substrate of the SSD 11. The attachment portion 55 includes an end surface 55a. The end surface 55a is provided at the end of the attachment portion 55 in the −Z direction and faces the −Z direction as a whole. The insertion portion 56 extends from the end surface 55a of the attachment portion 55 in the −Z direction. The −Z direction is an example of a first direction. The insertion portion 56 is formed in a plate shape that extends along a Y-Z plane. Note that the insertion portion 56 is not limited to this example.

The insertion portion 56 includes an end surface 56a and an outer circumferential surface 56b. The end surface 56a is provided at the end of the insertion portion 56 in the −Z direction and faces the −Z direction as a whole. The outer circumferential surface 56b is provided between the end surface 56a and the attachment portion 55. As illustrated in FIG. 8, the outer circumferential surface 56b includes an upper surface 56c, a lower surface 56d, and two lateral surfaces 56e. Note that the expression of “upper” and “lower” relating to the male connector 21 and the female connector 43 is an expedient expression based on, for example, their disposition in FIG. 8.

As illustrated in FIG. 7 and FIG. 8, the upper surface 56c is formed to be substantially flat and substantially faces the −X direction. As illustrated in FIG. 4, the lower surface 56d is located on the opposite side to the upper surface 56c. The lower surface 56d is formed to be substantially flat and substantially faces the +X direction. The two lateral surfaces 56e connect both ends of the upper surface 56c and the lower surface 56d in the Y direction. One of the lateral surfaces 56e substantially faces the +Y direction. The other of the lateral surfaces 56e substantially faces the −Y direction.

As illustrated in FIG. 7, the protrusions 57 protrude from the lower surface 56d of the insertion portion 56 substantially in the +X direction. The protrusions 57 are located in the vicinity of the end surface 56a. For example, the protrusions 57 are formed substantially in a hemispherical shape. Note that the locations and the shape of the protrusions 57 are not limited to this example.

As illustrated in FIG. 4, the two guides 58 extend from the attachment portion 55 substantially in the −Z direction. The two guides 58 are apart from each other in the Y direction. The two guides 58 are each provided with a guide groove 59. The guide grooves 59 extend in the +Z direction from the ends of the guides 58 in the −Z direction.

The contacts 52 are made of, for example, a metal such as copper and has conductivity. The plurality of contacts 52 each have a mounting portion 61 and a contact portion 62. The mounting portions 61 are provided on one end portions of the contacts 52. The mounting portions 61 protrude from the attachment portion 55 and are to be joined to pads of a substrate of the SSD 11 with, for example, solder. The contact portions 62 are provided on the other end portions of the contacts 52. The contact portions 62 of the plurality of contacts 52 are each provided on the upper surface 56c or the lower surface 56d of the insertion portion 56. The plurality of contacts 52 are arranged spaced apart from one another in the Y direction. The protrusions 57 are apart in the −Z direction from the end portions of the contacts 52 in the −Z direction. Note that the locations of the protrusions 57 are not limited to this example.

As illustrated in FIG. 5, the female connector 43 includes a housing 71, two guides 72, and a plurality of contacts 73. Note that the female connector 43 is not limited to this example.

The housing 71 is made of, for example, a synthetic resin and has insulation properties. The housing 71 includes an outer surface 71a and an inner surface 71b. The outer surface 71a fronts the outside of the housing 71. As illustrated in FIG. 7, the outer surface 71a includes an end surface 71c, an upper outer surface 71d, and a lower outer surface 71e.

The end surface 71c is provided at the end of the housing 71 in the +Z direction. The upper outer surface 71d is formed to be substantially flat and substantially faces the −X direction. The lower outer surface 71e is located on the opposite side to the upper outer surface 71d. The lower outer surface 71e is formed to be substantially flat and substantially faces the +X direction.

The housing 71 is provided with a concavity 75, a plurality of through holes 76 and 77, and a plurality of grooves 78 and 79. Note that the housing 71 is not limited to this example. The concavity 75 can also be referred to as an insertion opening. The through holes 76 and 77 are an example of through holes and holes. In FIG. 5, the grooves 78 and 79 are omitted.

As illustrated in FIG. 5, the concavity 75 opens on the end surface 71c and extends from the end surface 71c substantially in the −Z direction. The concavity 75 is a slit that extends along a Y-Z plane. Note that the concavity 75 is not limited to this example. The female connector 43 houses the insertion portion 56 of the male connector 21 in the concavity 75. The inner surface 71b of the housing 71 defines the concavity 75. The inner surface 71b includes a bottom surface 71f, an upper inner surface 71g, and a lower inner surface 71h illustrated in FIG. 7, and includes two lateral surfaces 71i illustrated in FIG. 8.

As illustrated in FIG. 7, the bottom surface 71f is provided at the end of the concavity 75 in the −Z direction. The bottom surface 71f and the end surface 56a of the insertion portion 56 face each other with a gap therebetween. Note that the end surface 56a and the bottom surface 71f may be in contact with each other.

The upper inner surface 71g, the lower inner surface 71h, and the lateral surfaces 71i are provided between the end surface 71c and the bottom surface 71f. The upper inner surface 71g and the lower inner surface 71h face each other via the concavity 75. The distance between the upper inner surface 71g and the lower inner surface 71h is slightly greater than the distance between the upper surface 56c and the lower surface 56d of the insertion portion 56.

In the state where the concavity 75 houses the insertion portion 56, the upper inner surface 71g and the upper surface 56c of the insertion portion 56 face each other with a slight gap therebetween. The lower inner surface 71h and the lower surface 56d of the insertion portion 56 face each other with a slight gap therebetween. In the state where the insertion portion 56 is fully housed in the concavity 75, the end surface 71c of the female connector 43 and the end surface 55a of the male connector 21 are in contact with each other, with no gap.

The housing 71 further includes an upper wall 81 and a lower wall 82. The upper wall 81 is an example of a first wall. The lower wall 82 is an example of a second wall. The upper wall 81 is a portion of the housing 71 between the upper outer surface 71d and the upper inner surface 71g. As a result, the upper wall 81 includes the upper outer surface 71d and the upper inner surface 71g, which is a portion of the inner surface 71b. The lower wall 82 is a portion of the housing 71 between the lower outer surface 71e and the lower inner surface 71h. As a result, the lower wall 82 includes the lower outer surface 71e and the lower inner surface 71h, which is another portion of the inner surface 71b.

The lower wall 82 is thinner than the upper wall 81. That is, the distance between the upper outer surface 71d and the upper inner surface 71g is greater than the distance between the lower outer surface 71e and the lower inner surface 71h. Note that the upper wall 81 and the lower wall 82 are not limited to this example.

As illustrated in FIG. 8, the two lateral surfaces 71i are provided at both ends of the concavity 75 in the Y direction. The two lateral surfaces 71i connect both ends of the upper inner surface 71g and the lower inner surface 71h in the Y direction. One of the lateral surfaces 71i faces the +Y direction. The other of the lateral surfaces 71i faces the −Y direction.

The two lateral surfaces 71i face each other via the concavity 75. The distance between the two lateral surfaces 71i is slightly greater than the distance between the two lateral surfaces 56e of the insertion portion 56. In the state where the concavity 75 houses the insertion portion 56, the lateral surfaces 71i and the lateral surfaces 56e of the insertion portion 56 face each other with slight gaps therebetween.

The housing 71 is further provided with two cutouts 83. The two cutouts 83 are formed inwardly of the two lateral surfaces 71i. As a result, the two cutouts 83 communicate with the concavity 75. The cutouts 83 are provided between the end surface 71c and the bottom surface 71f and open on the end surface 71c.

As illustrated in FIG. 7, the plurality of through holes 76 each penetrate substantially in the X direction through the end portion of the upper wall 81 in the −Z direction and open on the upper outer surface 71d and the upper inner surface 71g. The plurality of through holes 77 each penetrate substantially in the X direction through the end portion of the lower wall 82 in the −Z direction and open on the lower outer surface 71e and the lower inner surface 71h. As a result, the plurality of through holes 76 and 77 make the concavity 75 and the outside of the female connector 43 communicate with each other. The X direction is the thickness direction of the housing 71.

As illustrated in FIG. 8, the plurality of through holes 76 are arranged spaced apart from one another in the Y direction. The Y direction is perpendicular to (intersects with) the −Z direction. The Y direction is an example of a second direction. The plurality of through holes 77 are arranged spaced apart from one another in the Y direction.

As illustrated in FIG. 7, for example, the plurality of through holes 76 and 77 each include two recessed portions 85 and 86 and a round hole 87. The recessed portions 85 and 86 are each an elliptic concavity in a hemispherical shape. The recessed portion 85 opens on the upper outer surface 71d or the lower outer surface 71e, and the recessed portion 86 opens on the upper inner surface 71g or the lower inner surface 71h. The round hole 87 is a substantially circular hole and extends substantially in the X direction between the recessed portion 85 and the recessed portion 86.

Cross sections of the recessed portions 85 and 86 on the upper outer surface 71d, the lower outer surface 71e, the upper inner surface 71g, and the lower inner surface 71h are larger than a cross section of the round hole 87. That is, the through holes 76 and 77 are each expanded at both ends. Note that the through holes 76 and 77 are not limited to this example.

The insertion portion 56 of the male connector 21 is located between the upper wall 81 and the lower wall 82. The protrusions 57 protrude from the lower surface 56d of the insertion portion 56 toward the lower wall 82. The distance between the upper surface 56c of the insertion portion 56 and the ends of the protrusions 57 in the +X direction is greater than the distance between the upper inner surface 71g and the lower inner surface 71h.

Each of the protrusions 57 is engaged with one of the plurality of through holes 77. Abutting on edges of the through holes 77, the protrusions 57 constrain the male connector 21 from moving in the +Z direction with respect to the female connector 43. That is, being engaged with the through holes 77, the protrusions 57 constrain the insertion portion 56 from coming off from the concavity 75.

The plurality of grooves 78 are provided on the upper inner surface 71g. The plurality of grooves 79 are provided on the lower inner surface 71h. The plurality of grooves 78 and 79 are provided between the end surface 71c and the bottom surface 71f and open on the end surface 71c. As a result, the plurality of grooves 78 and 79 make the concavity 75 and the outside of the female connector 43 communicate with each other.

As illustrated in FIG. 8, the plurality of grooves 78 are arranged spaced apart from one another in the Y direction. The plurality of grooves 79 are arranged spaced apart from one another in the Y direction. The locations of the plurality of grooves 78 in the Y direction may be different from the locations of the plurality of grooves 79.

The housing 71 is located between the male connector 21 and the two guides 58. The two guides 72 of the female connector 43 protrude from both ends of the housing 71 in the Y direction and are engaged with the two guide grooves 59 of the male connector 21. Abutting on the ends of the guide grooves 59 in the +Z direction, the guides 72 constrain the male connector 21 from moving in the −Z direction with respect to the female connector 43.

The contacts 73 are made of, for example, a metal such as copper and has conductivity. As illustrated in FIG. 5, the plurality of contacts 73 each have a mounting portion 91 and a contact portion 92. The mounting portions 91 are provided on one end portions of the contacts 73. The mounting portions 91 protrude from the housing 71 and are to be joined to pads of a substrate 42 with, for example, solder. The contact portions 92 are provided on other end portions of the contacts 73. The contact portions 92 of the plurality of contacts 73 are each provided on the upper inner surface 71g or the lower inner surface 71h of the housing 71. The plurality of contacts 73 are arranged spaced away from one another in the Y direction.

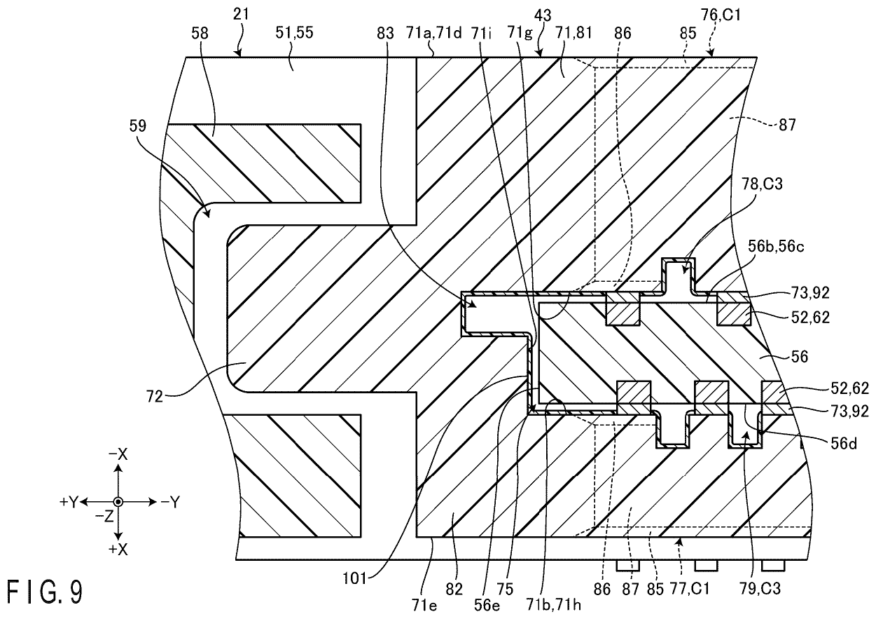

FIG. 9 is an exemplary sectional view partially illustrating the male connector 21 and the female connector 43 in the first embodiment in an enlarged manner. As illustrated in FIG. 9, the contact portion 92 of the female connector 43 comes into contact with the contact portion 62 of the male connector 21. As a result, the contacts 52 of the male connector 21 and the contacts 73 of the female connector 43 are electrically connected to each other.

The plurality of grooves 78 are each provided on the upper inner surface 71g between adjacent two of the plurality of contacts 73. The plurality of grooves 79 are each provided on the lower inner surface 71h between adjacent two of the plurality of contacts 73.

The female connector 43 further includes coating 101. The coating 101 is, for example, a film of polytetrafluoroethylene (PTFE). Note that the coating 101 is not limited to this example.

The coating 101 is provided on the inner surface 71b. The coating 101 repels the coolant L more than the inner surface 71b. That is, an angle of contact formed between a droplet of the coolant L and the coating 101 is larger than an angle of contact formed between a droplet of the coolant L and the inner surface 71b.

As mentioned above, the SSDs 11 are inspected with a plurality of test apparatuses 10. For example, when an inspection with a first test apparatus 10 is finished, a door 35 of a housing 12 is opened, and test units 13 are taken out of a chamber 31. In addition, a lid 46 is opened, and male connectors 21 are detached from female connectors 43 in the coolant L. The SSDs 11 are taken out of the coolant L in the housing chamber 45.

Next, the SSDs 11 are attached to test units 13 of a second test apparatus 10. That is, the SSDs 11 are immersed in the coolant L in a housing chamber 45, and the male connectors 21 are fitted into female connectors 43 in the coolant L. The test units 13 are housed in a chamber 31, and the SSDs 11 are inspected with the second test apparatus 10.

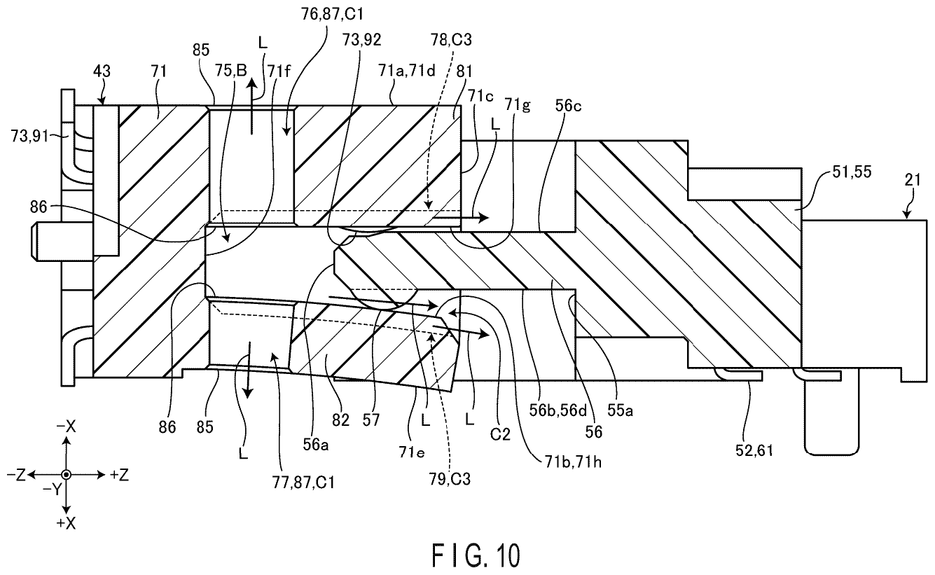

FIG. 10 is an exemplary sectional view illustrating the male connector 21 that is being inserted into the female connector 43 in the first embodiment. In a state where the male connector 21 is detached from the female connector 43, the concavity 75 of the female connector 43 is opened toward the outside on the end surface 71c. In contrast, as illustrated in FIG. 10, in a state where the insertion portion 56 of the male connector 21 is being inserted into the concavity 75, the insertion portion 56 at least partially closes a deep portion B of the concavity 75.

The deep portion B is a portion of the concavity 75 between the end surface 56a of the insertion portion 56 and the bottom surface 71f of the housing 71. That is, the deep portion B is an example of a portion of a concavity between the end of an insertion portion in the first direction and the end of the concavity in the first direction.

The coolant L has a high viscosity. For example, it is difficult for the coolant L to pass through the slight gap between the upper surface 56c of the insertion portion 56 and the upper inner surface 71g of the housing 71. If the coolant L in the deep portion B is not discharged, the coolant L stays in the deep portion B and may hinder the insertion portion 56 from being fully housed in the concavity 75. In other words, the coolant L staying in the deep portion B may hinder the end surface 71c of the female connector 43 and the end surface 55a of the male connector 21 from coming in contact with each other without a gap.

In the present embodiment, the through holes 76 and 77 make the deep portion B and the outside of the female connector 43 communicate with each other. That is, the female connector 43 is provided with the through holes 76 and 77 that make the deep portion B and the outside communicate with each other and serve as channels C1 when the insertion portion 56 is inserted into the concavity 75. The coolant L in the deep portion B is discharged to the outside through the through holes 76 and 77 serving as the channels C1.

In the present embodiment, when the insertion portion 56 is inserted into the concavity 75, the protrusions 57 press the lower wall 82, thereby causing the lower wall 82 to elastically deform. Thus, the concavity 75 is spread out by the protrusions 57, and the distance between the lower surface 56d of the insertion portion 56 and the lower inner surface 71h of the housing 71 is increased. The cutouts 83 extend the inner circumference of the concavity 75, thus making it easier for the concavity 75 to expand.

The protrusions 57 may press the contact portions 92 of the contacts 73 to cause the lower wall 82 to elastically deform. The protrusions 57 are made of a synthetic resin, and the contacts 73 are made of a metal. As a result, the protrusions 57 can be restrained from scratching the contacts 73.

In the Y direction, the length (width) of the protrusions 57 is less than the length (width) of the concavity 75. As a result, the protrusions 57 spreading out the concavity 75 provide the female connector 43 with a channel C2, which is a gap between the lower surface 56d of the insertion portion 56 and the lower inner surface 71h of the housing 71. The channel C2 makes the deep portion B and the outside communicate with each other. As a result, the coolant L in the deep portion B is discharged to the outside through the channel C2.

In the present embodiment, the plurality of grooves 78 and 79 make the deep portion B and the outside communicate with each other. As a result, the female connector 43 is provided with the grooves 78 and 79 that make the deep portion B and the outside communicate with each other and serve as channels C3 when the insertion portion 56 is inserted into the concavity 75. The coolant L in the deep portion B is discharged to the outside through the grooves 78 and 79 serving as the channels C3.

As described above, when the insertion portion 56 is inserted into the concavity 75, the coolant L in the deep portion B is discharged to the outside through at least one of the channels C1, C2, and C3. As a result, the insertion portion 56 is fully inserted into the concavity 75 without being hindered by the coolant L in the deep portion B. In the state where the insertion portion 56 is fully inserted into the concavity 75, the protrusions 57 are engaged with the through holes 77, thus reversing the elastic deformation of the lower wall 82.

The male connector 21 and the female connector 43 may be fitted together outside the coolant L. For example, the coolant L is discharged from the housing chamber 45 before the male connector 21 and the female connector 43 are fitted together. In this case, some of the coolant L may remain in the concavity 75.

For example, by blowing air into the concavity 75 with a blower in the state where the male connector 21 and the female connector 43 are not fitted together, the coolant L inside the concavity 75 is discharged through the through holes 76 and 77 and the grooves 78 and 79. The coolant L may be sucked from the concavity 75 with a suction machine. Alternatively, the coolant L can be discharged from the concavity 75 and through the grooves 78 and 79 by inclining the female connector 43 because the coolant L is repelled by the coating 101.

Since the coolant L is discharged from the concavity 75, the insertion portion 56 is fully inserted into the concavity 75 without being hindered by the coolant L in the deep portion B. As a result, the contacts 52 of the male connector 21 and the contacts 73 of the female connector 43 are electrically connected to each other without being hindered by the coolant L.

The coolant L and foreign matter such as dust may be discharged by letting a cleaning solution such as benzine flow from the concavity 75 to through holes 76 and 77. After the cleaning, by blowing air into the concavity 75 with a blower, some of the cleaning solution remaining inside the concavity 75 is discharged through the through holes 76 and 77 and the grooves 78 and 79.

In the test apparatus 10 according to the first embodiment described above, the male connector 21 includes the insertion portion 56 and is configured to be placed in the coolant L. The female connector 43 is configured to be placed in the coolant L. The female connector 43 includes the outer surface 71a, the concavity 75, and the channels C1, C2, and C3. The concavity 75 extends from the end surface 71c of the outer surface 71a in the −Z direction and houses the insertion portion 56. When the insertion portion 56 is inserted into the concavity 75, the channels C1, C2, and C3 make the outside and the deep portion B between the end surface 56a, which is the end of the insertion portion 56 in the −Z direction, and the bottom surface 71f, which is the end of the concavity 75 in the −Z direction, communicate with each other. Thus, the coolant L can pass through the channels C1, C2, and C3.

The male connector 21 and the female connector 43 are provided in the test apparatus 10 that can be subjected to immersion cooling. When the insertion portion 56 of the male connector 21 is inserted into the concavity 75 of the female connector 43 in the coolant L, some of the coolant L collects in the deep portion B. However, the channels C1, C2, and C3 make the deep portion B and the outside communicate with each other and can thus discharge the coolant L from the deep portion B to the outside. Therefore, the test apparatus 10 in the present embodiment enables the male connector 21 and the female connector 43 to be fitted together even when immersed in the coolant L.

The female connector 43 includes the inner surface 71b that defines the concavity 75. The channels C1 includes the through holes 76 and 77 that open on the inner surface 71b and make the deep portion B and the outside communicate with each other. Stated differently, the male connector 21 includes the insertion portion 56. The female connector 43 can be fitted to the male connector 21 and includes the housing 71. The housing 71 includes at least one through hole 76 or 77 penetrating the housing 71 in the thickness direction of the housing 71 and includes the concavity 75 that houses the insertion portion 56 and extends in the Z direction that is perpendicular to the thickness direction. The concavity 75 communicates with the through hole 76 or 77. That is, the female connector 43 is invariably provided with the through hole 76 or 77 serving as the channel C1. Thus, the test apparatus 10 in the present embodiment can easily discharge the coolant L collecting in the deep portion B to the outside through the channel C1. When the female connector 43 is taken out of the coolant L, some coolant L may remain inside the concavity 75. For example, by blowing air into the concavity 75 with a blower, the coolant L inside the concavity 75 is discharged from the through hole 76 or 77. Therefore, the test apparatus 10 in the present embodiment can restrain the coolant L from remaining inside the concavity 75.

The through hole 76 or 77 includes a plurality of through holes 76 and 77 that are arranged in the Y direction, which intersects with the −Z direction. Stated differently, the housing 71 includes the plurality of through holes 76 and 77. The plurality of through holes 76 and 77 are arranged spaced apart from one another in the Y direction, which is perpendicular to the thickness direction and the Z direction. The Y direction intersects with the −Z direction, which is a direction in which the insertion portion 56 is inserted into the concavity 75. As a result, the plurality of through holes 76 and 77 can keep their channel area that enables the discharge of the coolant L, until the insertion portion 56 is fully inserted into the concavity 75. Therefore, the test apparatus 10 in the present embodiment can easily discharge the coolant L collecting in the deep portion B to the outside through the channel C1.

The male connector 21 includes the protrusions 57 protruding from the insertion portion 56. The female connector 43 includes the inner surface 71b that defines the concavity 75. The female connector 43 is configured such that, when the insertion portion 56 is inserted into the concavity 75, the channel C2 is provided between the insertion portion 56 and the inner surface 71b by the protrusions 57 spreading out the concavity 75. That is, the channel C2 is temporarily provided when the insertion portion 56 is inserted into the concavity 75. Thus, the test apparatus 10 can restrain the channel C2 from making the deep portion B from constantly communicating with the outside and in turn restrain foreign matter from entering the deep portion B from the outside.

The connector includes the upper wall 81 and the lower wall 82. The upper wall 81 includes the upper inner surface 71g, which is a portion of the inner surface 71b. The lower wall 82 includes the lower inner surface 71h, which is another portion of the inner surface 71b. The lower wall 82 is thinner than the upper wall 81. The insertion portion 56 is located between the upper wall 81 and the lower wall 82. The protrusions 57 protrude from the insertion portion 56 toward the lower wall 82.

When the insertion portion 56 is inserted into the concavity 75, the protrusions 57 press the lower wall 82. Being pressed by the protrusions 57, the thin lower wall 82 easily deforms to stretch out the concavity 75. Therefore, the test apparatus 10 in the present embodiment can easily provide the channel C2 when the insertion portion 56 is inserted into the concavity 75.

The lower wall 82 is provided with the through holes 77 that open on the inner surface 71b. The protrusions 57 are configured to constrain the insertion portion 56 from coming off from the concavity 75 when being engaged with the through holes 77. Thus, the test apparatus 10 in the present embodiment can restrain an unintended dropping of the insertion portion 56 from the concavity 75 due to the thinness of the lower wall 82.

The female connector 43 includes the inner surface 71b that defines the concavity 75. The channels C3 include the grooves 78 and 79 that are provided on the inner surface 71b and make the deep portion B and the outside communicate with each other. Stated differently, the concavity 75 includes a plurality of grooves 78 and 79 that are arranged spaced apart from one another in the Y direction. That is, the female connector 43 is invariably provided with the grooves 78 and 79 serving as the channels C3. Thus, the test apparatus 10 in the present embodiment can easily discharge the coolant L collecting in the deep portion B to the outside through the channels C3. When the female connector 43 is taken out of the coolant L, some coolant L may remain inside the concavity 75. For example, by inclining the female connector 43, the coolant L inside the concavity 75 is discharged through the grooves 78 and 79. Therefore, the test apparatus 10 in the present embodiment can restrain the coolant L from remaining inside the concavity 75.

The male connector 21 and the female connector 43 are configured to be placed in the coolant L. The coolant L is movable in the Z direction along the plurality of grooves 78 and 79 and movable in the thickness direction along the through holes 76 and 77. That is, the grooves 78 and 79 and the through holes 76 and 77 can discharge the coolant L in the concavity 75 to the outside. Therefore, the male connector 21 and the female connector 43 in the present embodiment enable the male connector 21 and the female connector 43 to be fitted together even when immersed in the coolant L.

The female connector 43 includes the plurality of contacts 73 provided on the inner surface 71b. The grooves 78 and 79 are each provided on the inner surface 71b between adjacent two of the plurality of contacts 73. Thus, the gaps between the plurality of contacts 73 are expanded by the grooves 78 and 79. Therefore, the test apparatus 10 in the present embodiment can restrain the coolant L from staying in the gaps between the plurality of contacts 73 due to surface tension.

The female connector 43 includes the inner surface 71b that defines the concavity 75. The coating 101, which repels the coolant L more than the inner surface 71b, is provided on the inner surface 71b. Thus, the test apparatus 10 in the present embodiment can smoothly discharge the coolant L in the deep portion B to the outside. When the female connector 43 is taken out of the coolant L, some coolant L may remain inside the concavity 75. Since the coating 101 repels the coolant L, the coolant L inside the concavity 75 is easily discharged by, for example, inclining the female connector 43. Therefore, the female connector 43 in the present embodiment can restrain the coolant L from remaining inside the concavity 75.

The female connector 43 includes the outer surface 71a and the inner surface 71b. The inner surface 71b defines the concavity 75 opening on the outer surface 71a. The through holes 76 and 77 making the concavity 75 and the outside communicate with each other open on the inner surface 71b.

For example, in the case where the male connector 21 is fitted into the female connector 43 in the coolant L, some of the coolant L collects inside the concavity 75. However, the through holes 76 and 77 make the inside and the outside of the concavity 75 communicate with each other and can thus discharge the coolant L from the inside to the outside of the concavity 75. Therefore, the female connector 43 in the present embodiment can be fitted to the male connector 21 even when immersed in the coolant L. When the female connector 43 is taken out of the coolant L, some coolant L may remain inside the concavity 75. For example, by blowing air into the concavity 75 with a blower, the coolant L inside the concavity 75 is discharged from the through hole 76 or 77. Therefore, the female connector 43 in the present embodiment can restrain the coolant L from remaining inside the concavity 75.

### Second Embodiment

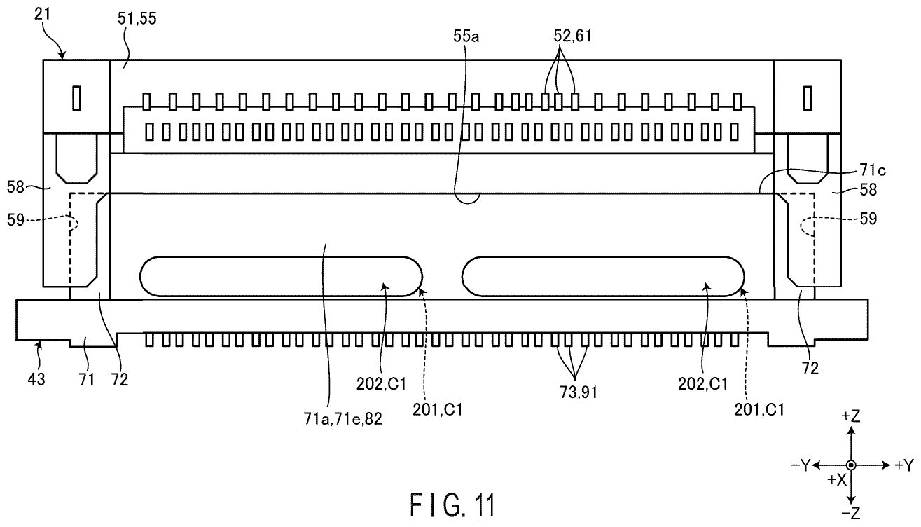

With reference to FIG. 11, a second embodiment will be described below. Note that, in the following description of multiple embodiments, the constituent elements having the same functions as the previously described constituent elements are denoted by the same reference numerals as the previously mentioned constituent elements, and the description thereof may be omitted. Furthermore, a plurality of constituent elements denoted by the same reference numerals are not necessarily common in all of their functions and properties and may have different functions and properties according to the respective embodiments.

FIG. 11 is an exemplary plan view illustrating a male connector 21 and a female connector 43 according to the second embodiment. As illustrated in FIG. 11, a housing 71 in the second embodiment is provided with a plurality of through grooves 201 and 202 instead of the plurality of through holes 76 and 77. The through grooves 201 and 202 are substantially equivalent to the through holes 76 and 77 except for the points described below.

The through grooves 201 and 202 extend in a Y direction. Two through grooves 201 penetrate through an upper wall 81 and are arranged spaced apart from each other in the Y direction. Two through grooves 202 penetrate through a lower wall 82 and are arranged spaced apart from each other in the Y direction.

In a test apparatus 10 in the second embodiment described above, the through grooves 201 and 202 extend in the Y direction. The Y direction intersects with a −Z direction, which is a direction in which an insertion portion 56 is inserted into a concavity 75. As a result, the through grooves 201 and 202 can keep their channel area that enables the discharge of coolant L, until the insertion portion 56 is fully inserted into the concavity 75. Therefore, the test apparatus 10 in the present embodiment can easily discharge coolant L collecting in a deep portion B to the outside through channels C1.

### Third Embodiment

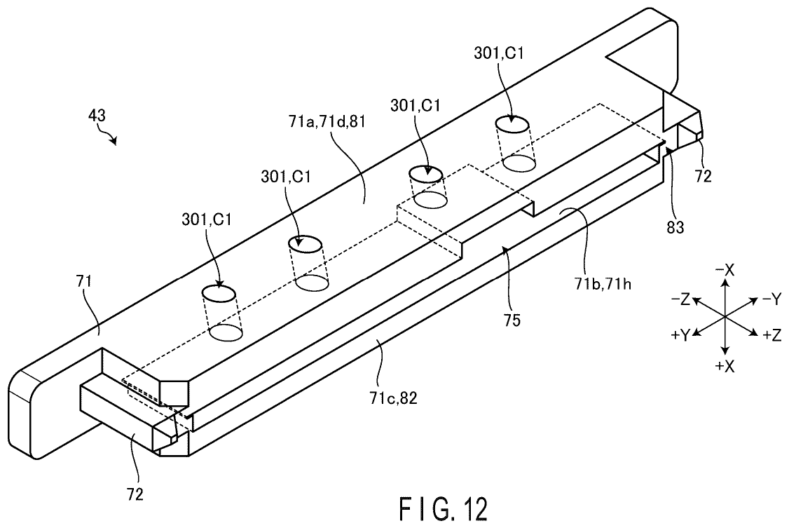

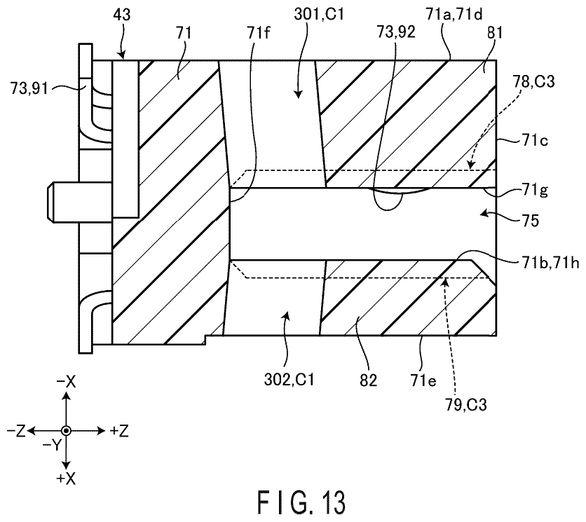

With reference to FIG. 12 and FIG. 13, a third embodiment will be described below. FIG. 12 is an exemplary perspective view illustrating a female connector 43 according to the third embodiment. FIG. 13 is an exemplary sectional view illustrating the female connector 43 according to the third embodiment. As illustrated in FIG. 12 and FIG. 13, a housing 71 in the third embodiment is provided with a plurality of through holes 301 and 302 instead of the plurality of through holes 76 and 77. The through holes 301 and 302 are substantially equivalent to the through holes 76 and 77 except for the points described below.

The plurality of through holes 301 and 302 each have a circular cross section. The through holes 301 penetrate through the upper wall 81 in a direction that intersects obliquely with the upper inner surface 71g. As a result, as illustrated in FIG. 12, the edges of the through holes 301 on the upper outer surface 71d and the upper inner surface 71g are each formed in an elliptic shape that is larger than the cross section of the through holes 301.

The through holes 302 penetrate through the lower wall 82 in a direction that intersects obliquely with the lower inner surface 71h. As a result, the edges of the through holes 302 on the lower outer surface 71e and the lower inner surface 71h are each formed in an elliptic shape that is larger than the cross section of the through holes 302.

In a test apparatus 10 in the third embodiment described above, the through holes 301 and 302 extend from the inner surface 71b in a direction that intersects obliquely with the inner surface 71b. Thus, the channel area of the through holes 301 and 302 on the inner surface 71b is increased. Therefore, the test apparatus 10 in the present embodiment can easily discharge coolant L collecting in a deep portion B to the outside through channels C1.

In each of the above-described embodiments, the test apparatus 10 is an example of the information processing apparatus. However, the information processing apparatus is not limited to these examples. For example, the information processing apparatus may be another type of an apparatus, such as a server that includes an immersion cooling device.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. An information processing apparatus comprising:
a male connector including an insertion portion; and
a female connector including:
an outer surface;
a concavity that extends from the outer surface in a first direction and is configured to house the insertion portion; and
a coolant channel that extends from a portion of the concavity to outside the female connector and through which coolant passes when the insertion portion is inserted into the concavity while the male connector and the female connector are placed in the coolant, wherein the portion is located between an end of the insertion portion in the first direction and an end of the concavity in the first direction.

2. The information processing apparatus of claim 1, wherein
the female connector includes an inner surface defining the concavity, and
the coolant channel includes a through hole that is formed inwardly of the inner surface and extends in a direction crossing the first direction to the outside of the female connector.

3. The information processing apparatus of claim 2, wherein the through hole includes at least either a through groove or a plurality of through holes, the through groove extending in a second direction intersecting with the first direction, the plurality of through holes being arranged in the second direction.

4. The information processing apparatus of claim 1, wherein
the male connector includes a protrusion that protrudes from the insertion portion, and
the female connector includes an inner surface defining the concavity and is configured such that, when the insertion portion is inserted into the concavity, the protrusion expands the concavity to provide another coolant channel between the insertion portion and the inner surface.

5. The information processing apparatus of claim 4, wherein
the female connector includes a first wall and a second wall, the first wall including a portion of the inner surface, the second wall including another portion of the inner surface and being thinner than the first wall,
the insertion portion is located between the first wall and the second wall, and
the protrusion protrudes from the insertion portion toward the second wall.

6. The information processing apparatus of claim 5, wherein
the second wall is provided with a hole that is formed inwardly of the inner surface, and
the protrusion, when engaged with the hold, constrains the insertion portion from detaching from the concavity.

7. The information processing apparatus of claim 1, wherein
the female connector includes an inner surface defining the concavity, and
the coolant channel includes a groove provided on the surface and extending in the first direction.

8. The information processing apparatus of claim 7, wherein
the female connector includes a plurality of contacts provided on the inner surface, and
the groove is provided on the inner surface between adjacent two of the plurality of contacts.

9. The information processing apparatus of claim 1, wherein the female connector includes an inner surface defining the concavity and is provided, on the inner surface, with coating that repels the coolant more than the inner surface.

10. A connector comprising:
an outer surface; and
an inner surface that defines a concavity that opens to the outer surface and through which a through hole is formed,
wherein the concavity communicates with an outside of the connector via the through hole.

11. The connector of claim 10, wherein the concavity extends in a first direction to accommodate an insertion portion of another connector being inserted in the first direction, and the through hole extends in a second direction crossing the first direction.

12. The connector of claim 11, wherein the second direction is perpendicular to the first direction.

13. The connector of claim 11, wherein the second direction is oblique with respect to the first direction.

14. The connector of claim 11, wherein a plurality of through holes is formed through the inner surface and to be spaced apart from each other in a third direction crossing the first and second directions.

15. The connector of claim 10, wherein the inner surface has a first surface that faces a second surface, and the through hole is formed through both the first surface and the second surface.

16. The connector claim 15, wherein the first inner surface includes a plurality of first grooves extending the first direction and the second inner surface includes a plurality of second grooves extending in the first direction.

17. A connector comprising:
a male connector that includes an insertion portion; and
a female connector that is capable of being fitted with the male connector and includes a housing, wherein
the housing includes:
at least one through hole that penetrates the housing in a thickness direction of the housing; and
an insertion opening that is configured to house the insertion portion and extends in a first direction perpendicular to the thickness direction, and
the insertion opening communicates with the through hole.

18. The connector of claim 17, wherein
the housing includes a plurality of through holes each of which penetrates the housing in the thickness direction of the housing, and
the plurality of through holes are arranged spaced apart from one another in a second direction perpendicular to the thickness direction and the first direction.

19. The connector of claim 18, wherein the insertion opening includes a plurality of grooves that are arranged spaced apart from one another in the second direction.

20. The connector of claim 19, wherein
when the male connector and the female connector are fitted together while being placed in coolant, and
the coolant moves in the first direction along the plurality of grooves and moves in the thickness direction along the through holes.
